(19) United States
(12) Patent Application Publication
(10) Pub. No.: US 2026/0130156 A1
(43) Pub. Date: May 7, 2026

(54) SUBSTRATE PROCESSING APPARATUS AND SUBSTRATE PROCESSING METHOD USING THE SAME

(71) Applicant: SAMSUNG ELECTRONICS CO., LTD., Suwon-si (KR)

(72) Inventors: Yoonjae KIM, Suwon-si (KR); Juhyung LEE, Suwon-si (KR); Minwoo RHEE, Suwon-si (KR); Junhong MIN, Suwon-si (KR); Seungdon LEE, Suwon-si (KR); Hyunjin LEE, Suwon-si (KR); Hojin LEE, Suwon-si (KR); Joohee JANG, Suwon-si (KR)

(21) Appl. No.: 19/377,804

(22) Filed: Nov. 3, 2025

(30) Foreign Application Priority Data
Nov. 5, 2024 (KR) 10-2024-0155669

(51) Int. Cl. H01L 21/67; H01L 21/68

(52) U.S. Cl. CPC H10P 72/0404; H10P 72/0434; H10P 72/53

(57) ABSTRACT

A substrate processing apparatus includes a substrate stage configured to support and rotate a substrate, a dispenser configured to eject a solution toward an edge of the substrate, and a heater configured to heat at least part of the edge of the substrate, wherein the dispenser and the heater are synchronized with an encoder signal of the substrate stage.

### CROSS-REFERENCE TO RELATED APPLICATIONS

This application is based on and claims priority under 35 U.S.C. § 119 to Korean Patent Application No. 10-2024-0155669, filed on Nov. 5, 2024, in the Korean Intellectual Property Office, the disclosure of which is incorporated by reference herein in its entirety.

### BACKGROUND

The inventive concept relates to a substrate processing apparatus and a substrate processing method using the substrate processing apparatus, and more specifically, to a device and method for processing an edge of a substrate.

After a process of bonding wafers to each other is performed in a semiconductor device manufacturing process, a grinding process may be performed to reduce a thickness of a wafer. There may be a gap (or an un-bonding area) in which wafers are not in contact with each other in a structure in which the wafers are bonded to each other. A wafer structure in which the gap is formed may have weak mechanical strength, and accordingly, the wafer structure may be broken (for example, chipping may occur) in a subsequent process, such as a grinding process.

### SUMMARY OF THE INVENTION

The inventive concept provides a substrate processing apparatus that prevents damage, such as cracking and chipping of a wafer, and a substrate processing method using the substrate processing apparatus.

Also, objects of the inventive concept are not limited to the objects described above, and the other objects may be clearly understood by those skilled in the art from the description below.

According to an aspect of the inventive concept, a substrate processing apparatus includes a substrate stage configured to support and rotate a substrate, a dispenser configured to eject a solution toward an edge of the substrate, and a heater configured to heat at least part of the edge of the substrate, wherein operation of the dispenser and the heater are synchronized with a signal from an encoder associated with the substrate stage.

According to another aspect of the inventive concept, a substrate processing method includes obtaining a signal from an encoder associated with a substrate stage that is configured to support a substrate, ejecting a solution, via a dispenser, toward an edge of the substrate in response to an ejection signal that is synchronized with the encoder signal, heating at least part of an edge of the substrate, via a heater, in response to a heat signal that is synchronized with the encoder signal, and obtaining vision information by capturing an image of the edge of the substrate.

According to another aspect of the inventive concept, a substrate processing apparatus includes a substrate stage configured to support a substrate including a first substrate and a second substrate in contact with each other in a first direction, a dispenser configured to eject a solution in a second direction to a space between the first substrate and the second substrate, wherein the second direction is transverse to the first direction, a heater positioned adjacent to the substrate in the second direction, an encoder configured to generate an encoder signal including rotation information of the substrate stage, a dispensing controller configured to control operation of the dispenser by using an ejection signal synchronized with the encoder signal, a current controller configured to control operation of the heater by using a heat signal synchronized with the encoder signal, and a vision system configured to obtain vision information by capturing an image of the substrate.

### BRIEF DESCRIPTION OF THE DRAWINGS

Embodiments of the inventive concept will be more clearly understood from the following detailed description taken in conjunction with the accompanying drawings in which:

FIG. 1 is a perspective view schematically illustrating a substrate processing apparatus according to an embodiment;

FIG. 2A is a cross-sectional view illustrating an example of a substrate structure processed by using a substrate processing method according to an embodiment;

FIG. 2B is a plan view illustrating an example of a substrate structure processed by using a substrate processing method according to an embodiment;

FIG. 3 is a view illustrating a dispenser of a substrate processing apparatus according to an embodiment;

FIG. 4 is a schematic cross-sectional view of a substrate structure illustrating a substrate processing apparatus according to an embodiment;

FIG. 5 is a schematic cross-sectional view of a substrate structure illustrating a substrate processing apparatus according to an embodiment; and

FIG. 6 is a schematic flowchart illustrating a substrate processing method according to an embodiment.

### DETAILED DESCRIPTION

Hereinafter, embodiments of the inventive concept are described in detail with reference to the attached drawings. The same reference numerals are used for the same components in the drawings, and redundant descriptions thereof are omitted.

In the following embodiments, the terms first, second, and so on are used for the purpose of distinguishing one component from another component without being used in a limited sense.

In the following embodiments, singular expression includes plural expressions unless the context clearly indicates otherwise.

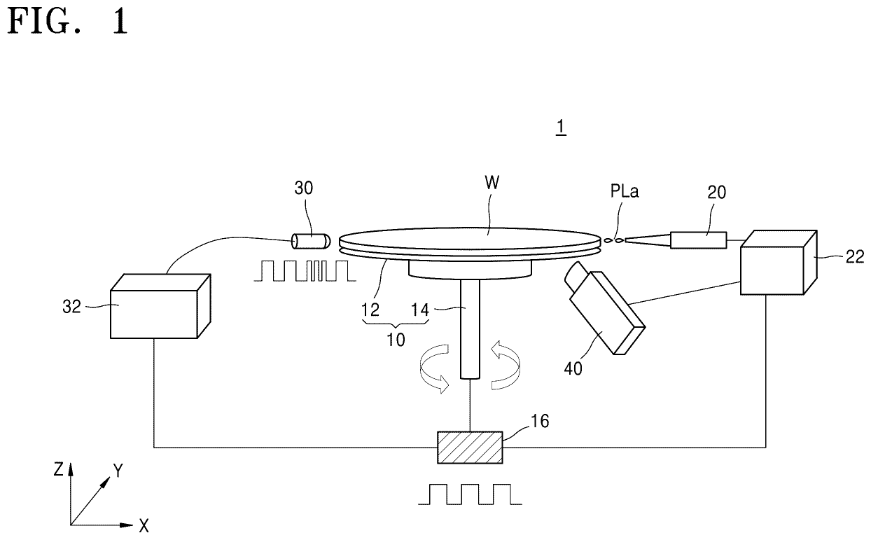

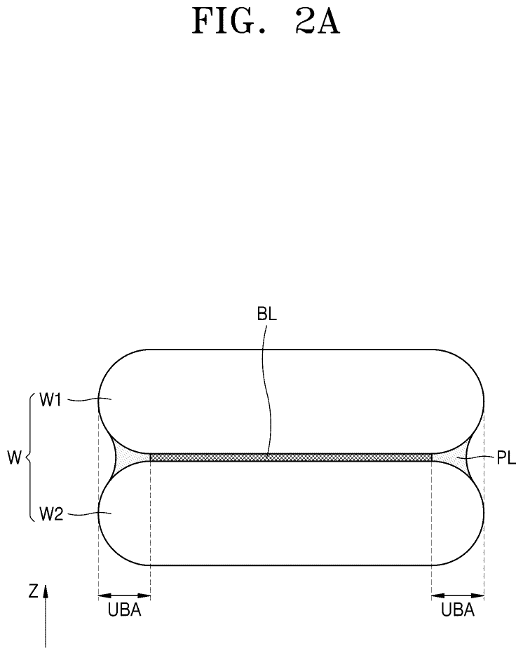

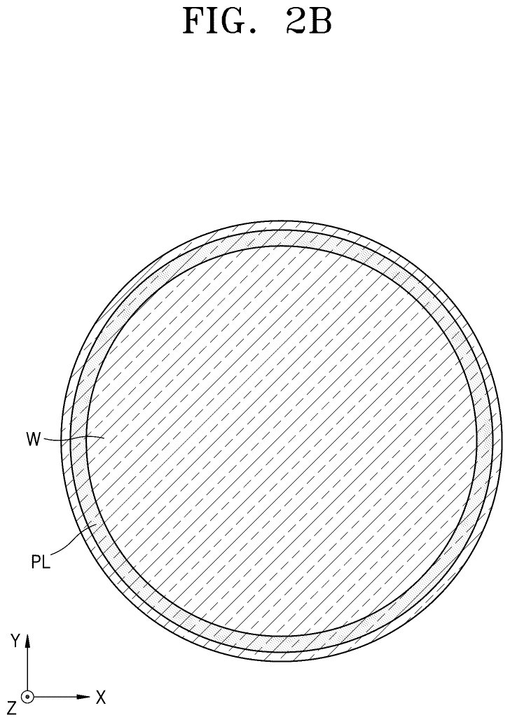

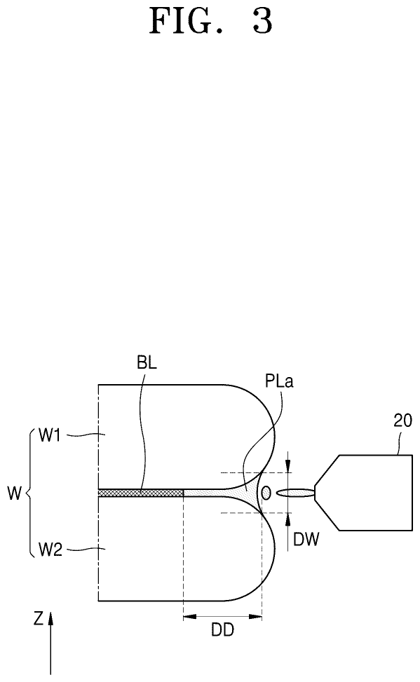

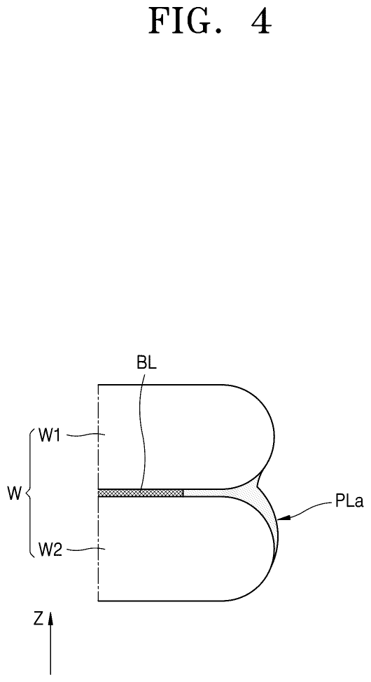

FIG. 1 is a perspective view schematically illustrating a substrate processing apparatus according to an embodiment. FIG. 2A is a cross-sectional view illustrating an example of a substrate structure processed by using a substrate processing method according to an embodiment. FIG. 2B is a plan view illustrating an example of a substrate structure processed by using the substrate processing method according to the embodiment. FIG. 3 is a view illustrating a dispenser of the substrate processing apparatus according to the embodiment. FIG. 4 is a schematic cross-sectional view of a substrate structure illustrating the substrate processing apparatus according to the embodiment.

Referring to FIG. 1, a substrate processing apparatus 1 according to various embodiments of the inventive concept may include a substrate stage 10, a dispenser 20, and a heater 30. The substrate stage 10 may be provided in a chamber for performing a semiconductor device manufacturing process on a substrate W. The substrate stage 10 may include a chuck table 12 supporting the substrate W and a chuck rotator 14 rotating the chuck table 12. In a plan view, an outer shape of the chuck table 12 may be circular. The chuck table 12 may be configured as a disc-shaped frame formed of an alloy, for example, ceramics or stainless steel on an upper surface of the chuck table

The substrate W may be placed on the upper surface of the chuck table 12. In one embodiment, a lower surface of the substrate W may come into direct contact with the chuck table 12. Various methods for fixing the substrate W onto the chuck table 12 may be used. For example, the chuck table 12 may include a separate external member for fixing the substrate W. The separate external member may be a fixing member for fixing an upper surface or side surface of the substrate W. The chuck table 12 may include a member, such as a support plate, for fixing the substrate W onto the upper surface. For example, a member, such as a support plate, formed to have a shape of a porous disc may be placed on an upper surface of the chuck table 12 and comes into contact with the substrate W. The substrate W may be fixed by a suction source installed inside the chuck table 12.

In one embodiment, the chuck table 12 may be connected to a suction source through a path or valve installed inside the chuck table 12. The suction source may come into contact with a lower surface of the substrate W placed on the chuck table 12 to fix the substrate W with the suction force generated according to the negative pressure of the suction source. For example, the suction source may be air. The chuck table 12 may include at least one suction hole to fix the substrate W according to negative pressure of the suction source. For example, the suction source supplied through at least one suction hole of the chuck table 12 may maintain or release the suction of the substrate W. A method of fixing and/or supporting the substrate W by the chuck table 12 described above is a non-limiting example, and other methods may also be used instead of the method described above.

The chuck table 12 may be supported by the chuck rotator 14. The chuck table 12 may rotate by receiving rotational force from the chuck rotator 14. The chuck table 12 may be rotated clockwise or counterclockwise by the chuck rotator 14. In one embodiment, the chuck table 12 may be rotated at a preset angular velocity by the chuck rotator 14. Accordingly, the substrate W placed on the chuck table 12 may be rotated at a preset angular velocity by the chuck table 12.

Referring to FIG. 1 and FIG. 2A, the substrate W supported by the chuck table 12 may include a first substrate W1 and a second substrate W2. The first substrate W1 and the second substrate W2 may each be bulk silicon or silicon-on-insulator (SOI). The first substrate W1 and the second substrate W2 may each be a silicon substrate, or may include another material, such as silicon germanium, silicon germanium on insulator (SGOI), indium antimonide, lead telluride, indium arsenide, indium phosphide, gallium arsenide, or gallium antimonide but are not limited thereto. In one embodiment, the first substrate W1 and the second substrate W2 may each include a device region in which a device pattern is formed.

The first substrate W1 may overlap the second substrate W2 in a vertical direction (for example, the Z direction). The first substrate W1 may be in contact with the second substrate W2 by a bonding layer BL in the vertical direction (for example, the Z direction). The bonding layer BL may include a first wiring pattern adjacent to the first substrate W1 and a first passivation layer surrounding the first wiring pattern. The bonding layer BL may include a second wiring pattern adjacent to the second substrate W2 and a second passivation layer surrounding the second wiring pattern. In one embodiment, the first wiring pattern may be electrically connected to the second wiring pattern. The first substrate W1 may be bonded to the second substrate W2 by bonding of the first passivation layer and the second passivation layer of the bonding layer BL.

In one embodiment, ends of the first substrate W1 and the second substrate W2 may be rounded. As the first substrate W1 is bonded to the second substrate W2, there may be an un-bonding area UBA at an edge of the substrate W. The un-bonding area UBA may be an area where the first substrate W1 is not in contact the second substrate W2. Referring to FIG. 2A and FIG. 2B, a protective layer PL may be formed in the un-bonding area UBA of the substrate W. The protective layer PL may be formed in a ring shape along the edge of the substrate W. The protective layer PL may be in the un-bonding area UBA of the substrate W to fill a space between the first substrate W1 and the second substrate W2. The protective layer PL may prevent the substrate W from being broken or so on during a semiconductor process. The substrate processing apparatus 1 according to an embodiment illustrated in FIG. 1 may perform a process of forming the bonding layer BL between the first substrate W1 and the second substrate W2.

An encoder 16 may be electrically connected to the substrate stage 10. The encoder 16 may measure a position of the substrate W or send feedback such that a position of the substrate stage 10 may be adjusted in real time. The encoder 16 may use a phase signal and/or a pulse signal to increase accuracy.

As illustrated in FIG. 1, when the substrate stage 10 rotates, the encoder 16 may measure an angle and direction of rotation of the substrate stage 10 in real time, convert the measured angle and direction into signals, provide feedback to a position control system, and so on, and accordingly, the precision of a rotation operation may be maintained. In one embodiment, the encoder 16 may be a rotary encoder. The dispenser 20 and the heater 30 described below may each be synchronized with a signal (hereinafter, an encoder signal) generated by the encoder 16. The term “synchronized”, as used herein, refers to events, actions, or processes occurring at the same time or being coordinated to happen simultaneously. Thus, the dispenser 20 and the heater 30 may operate simultaneously in response to a signal generated by the encoder 16. The encoder signal may include rotation information of the substrate stage 10.

The substrate processing apparatus 1 may include the dispenser 20. The dispenser 20 may accurately and uniformly ejects a desired amount of a material (for example, a solution) onto the substrate W. In one embodiment, the dispenser 20 may form the protective layer PL on an edge of the substrate W. The dispenser 20 may eject a solution to a side surface of the substrate W.

Referring to FIG. 3, the dispenser 20 may be horizontally separated from the first substrate W1 and the second substrate W2 and may eject a protective solution PLa in the horizontal direction. The dispenser 20 may eject a solution (for example, the protective solution PLa) to a space between the first substrate W1 and the second substrate W2. In one embodiment, a position of the dispenser 20 may eject the protective solution PLa in a fixed state while the substrate stage 10 rotates. A size of one drop of the protective solution PLa ejected by the dispenser 20 may be a micro unit.

The protective solution PLa ejected from the dispenser 20 may be safely placed on an un-bonding area (UBA, see FIG. 2A) of the substrate W. A depth DD of the area where the protective solution PLa is safely placed may be, for example, about 100 micrometers to about 300 micrometers. A width DW of the area where the protective solution PLa is safely placed may be in about 200 micrometers to about 500 micrometers.

In general, the protective solution PLa has a low viscosity to fill a gap formed in the un-bonding area UBA between the first substrate W1 and the second substrate W2, and may be ejected by the dispenser 20 in a horizontal direction (for example, the Z direction) rather than a vertical direction. The protective solution PLa may flow along a side surface of the second substrate W2 at the bottom as illustrated in FIG. 4 due to gravity, and it may be difficult for the protective layer PL to have a desired position and thickness.

Referring to FIG. 1, the substrate processing apparatus 1 according to various embodiments may include the heater 30 that heats at least part of an edge of the substrate W, and the heater 30 operates together with the dispenser 20 at an appropriate timing, and accordingly, the flow of the protective solution PLa ejected from the dispenser 20 may be controlled.

In one embodiment, the heater 30 may be separated from the substrate stage 10 in the horizontal direction (for example, an XY plane direction). The heater 30 may be adjacent to the substrate W in the horizonal direction. The heater 30 may be on one side of the edge of the substrate W. While the substrate stage 10 rotates, a position of the heater 30 may be fixed and transfers heat toward the substrate W, and accordingly, the temperature of the edge of the substrate W and/or the protective solution PLa may be increased.

The heater 30 may control the temperature of the substrate W placed on the substrate stage 10 (specifically, the chuck table 12) to supply heat such that substrate processing may be performed. The heater 30 may pre-cure and/or completely cure the protective solution PLa. In one embodiment, the heater 30 may include a heater electrode made of a metal, such as tungsten (W), copper (Cu), nickel (Ni), molybdenum (Mo), titanium (Ti), nickel-chromium alloy (Ni—Cr alloy), or nickel-aluminum alloy (Ni—Al alloy), or a conductor, such as tungsten carbide (WC), molybdenum carbide (MoC), or titanium nitride (TiN).

Referring to FIG. 1, the dispenser 20 and the heater 30 included in the substrate processing apparatus 1 according to an embodiment may each be synchronized with a signal (an encoder signal) of the encoder 16. Here, synchronization may mean that different elements are in harmony according to a certain time, order, state, and/or condition. Because the dispenser 20 and the heater 30 are each synchronized with the encoder signal, the substrate stage 10, the dispenser 20, and the heater 30 may be processed according to a precise timing and order while operating.

In one embodiment, the substrate processing apparatus 1 may further include a dispensing controller 22 connected to the dispenser 20. The dispensing controller 22 may control whether the dispenser 20 is operating, the coating amount of the protective solution PLa, a coating speed, a coating strength, coating time, and so on. The dispensing controller 22 may be synchronized with the encoder signal of the encoder 16. The dispensing controller 22 may be electrically connected to the encoder 16. The dispensing controller 22 may control operation of the dispenser 20 through an ejection signal synchronized with the encoder signal.

In one embodiment, the substrate processing apparatus 1 may further include a current controller 32 connected to the heater 30. The heater 30 may be electrically connected to the current controller 32. The heater 30 may release heat as a conductor of the heater 30 is heated by power output from the current controller 32, for example, an alternating current (AC) voltage.

The current controller 22 may control whether the heater 30 operates, the intensityh of the heater 30, heating time, and so on. The current controller 22 may be synchronized with the encoder signal. The current controller 22 may be electrically connected to the encoder 16. The current controller 22 may control operation of the heater 30 through a heat signal synchronized with the encoder signal.

Although FIG. 1 illustrates that the dispensing controller 22 and the current controller 32 are configured separately from the dispenser 20 and the heater 30, the embodiments are not limited thereto. The dispensing controller 22 and the current controller 32 may be respectively included in the dispenser 20 and the heater 30.

Referring to FIG. 1, the substrate processing apparatus 1 according to various embodiments may include a vision system 40. The vision system 40 may obtain vision information by capturing an image of at least part of the substrate W. The vision system 40 may obtain vision information by capturing an image of at least part of an edge of the substrate W. The vision information may include a position of the protective solution PLa (or the protective layer PL). The vision system 40 may include a camera and an image processing module.

The vision system 40 may detect and analyze a state of the substrate W (specifically, a state of the protective solution PLa on the substrate W) by using the camera and the image processing software of the image processing module. In one embodiment, the image processing module may analyze an image (or a video) captured by the camera, extract defects or position information, and generate data necessary for controlling a process. In one embodiment, the image processing may also be performed through a deep learning model.

As illustrated in FIG. 4, a protective solution is provided to the substrate W in the horizontal direction by the dispenser 20, and accordingly, the protective solution PLa may flow in the vertical direction (for example, the-Z direction) due to gravity. In this regard, the vision system 40 may determine whether the protective solution PLa flows down more than a reference value. The vision information of the vision system 40 may include information on whether the protective solution PLa flows down more than the reference value. In one embodiment, the dispenser 20 and the heater 30 may each be turned on or off based on the vision information.

In one embodiment, the vision system 40 may transmit the vision information to the dispenser 20. The vision system 40 may transmit the vision information to the dispensing controller 22, and the dispensing controller 22 may control operation of the dispenser 20 based on the vision information. That is, the dispenser 20 may operate based on the vision information of the vision system 40. For example, the vision system 40 may transmit, to the dispensing controller 22, vision information including the determination that the protective solution PLa exceeds a preset reference value through image processing of an image (or a video) of the substrate W, and accordingly, the dispensing controller 22 may turn off the dispenser 20.

In one embodiment, the vision system 40 may transmit the vision information to the heater 30. The vision system 40 may transmit the vision information to the current controller 32, and the current controller 32 may control operation of the heater 30 based on the vision information. That is, the heater 30 may operate based on the vision information of the vision system 40. For example, the vision system 40 may transmit, to the current controller 32, vision information including determination that the protective solution PLa exceeds a preset reference value through image processing of an image of the substrate W, and accordingly, the current controller 32 may turn on the heater 30.

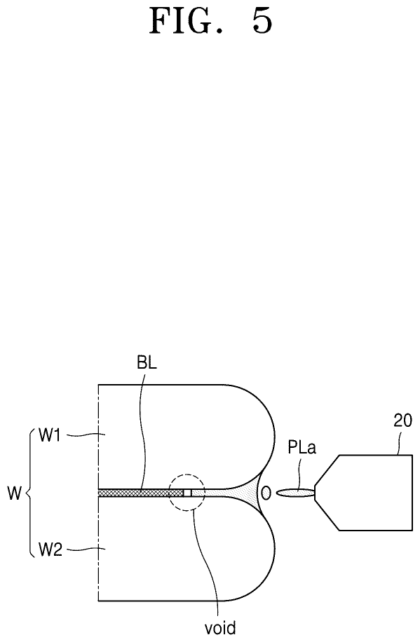

FIG. 5 is a schematic cross-sectional view of a substrate structure illustrating a substrate processing apparatus according to an embodiment.

Referring to FIG. 5, when the protective solution PLa is provided to the first substrate W1 and the second substrate W2 through the dispenser 20, the protective solution PLa may not completely permeate into a side surface of the bonding layer BL right away. That is, a void sealed with the protective solution PLa and the bonding layer BL may be formed between the first substrate W1 and the second substrate W2.

In one embodiment, the vision system 40 may check a distance that the protective solution PLa moves toward the center of the first substrate W1 and the second substrate W2. Alternatively, the vision system 40 may determine whether the protective solution PLa move to a position in which the protective solution PLa comes into contact with the bonding layer BL between the first substrate W1 and the second substrate W2.

When the amount of solution applied to the substrate W is small (that is, at the beginning when the dispenser 20 ejects the protective solution PLa, the solution may not flow down in the vertical direction due to a surface tension and the viscosity of the solution. Thereafter, as the amount of the solution applied to the substrate W increases, the solution may flow along a side surface of the substrate W. The heater 30 included in the substrate processing apparatus 1 according to an embodiment may pre-cure a part of the protective solution PLa applied to the substrate W before all of the necessary protective solution PLa is applied. Therethrough, the protective solution PLa may be prevented from flowing down in the vertical direction, and the flow of the protective solution PLa may be controlled such that the protective solution PLa between the first substrate W1 and the second substrate W2 may flow to the center of the substrate W to fill the void.

In one embodiment, the heater 30 may heat at least part of an edge of the substrate W for multiple periods of time separated from each other. For example, the heater 30 may be turned off to pre-cure the protective solution PLa after one operation, and then turned on again to completely cure the protective solution PLa.

In one embodiment, the vision system 40 may identify a certain position of the substrate W where the protective solution PLa flows in the vertical direction. The vision system 40 may transmit vision information including the certain position of the substrate W to the heater 30 (specifically, the current controller 32). Accordingly, the heater 30 may heat the certain position of the substrate W on the rotating substrate stage 10 as a target.

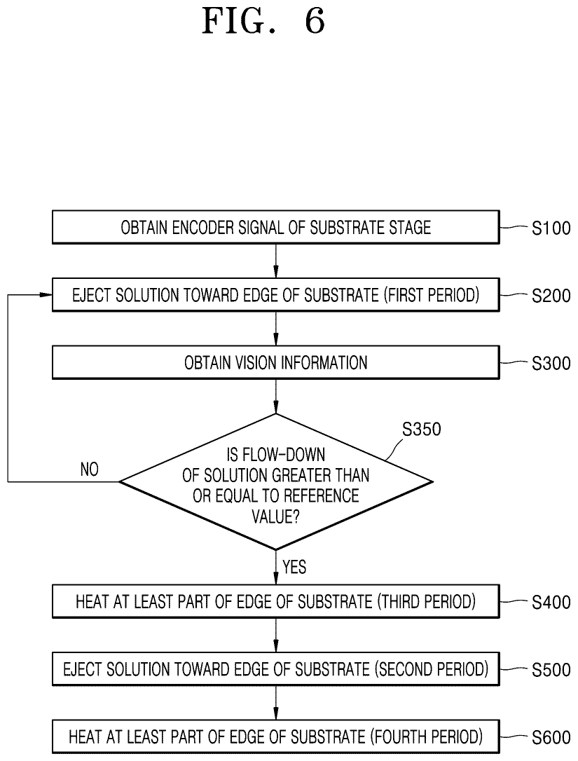

FIG. 6 is a schematic flowchart illustrating a substrate processing method according to an embodiment. The substrate processing method according to the embodiment may be performed by the substrate processing apparatus 1 described above with reference to FIG. 1.

Referring to FIG. 6 together with FIG. 1, the substrate processing method according to various embodiments may include operation S100 of obtaining an encoder signal of the substrate stage 10, operation S200 of ejecting a solution (for example, the protective solution PLa) toward an edge of the substrate W, operation S300 of obtaining vision information, and operation S400 of heating at least part of the edge of the substrate W.

The operation S100 of obtaining an encoder signal of the substrate stage 10 may be performed by the encoder 16. The encoder signal of the substrate stage 10 supporting the substrate W may include rotation information of the substrate W. The encoder signal may be obtained by measuring, by the encoder 16, a rotation angle, a rotation direction, and so on of the substrate stage 10 in real time.

The operation S100 of ejection a solution toward the edge of the substrate W may be performed by the dispenser 20. The dispenser 20 may eject the solution based on an ejection signal synchronized with the encoder signal. The operation S400 of heating at least part of the edge of the substrate W may be performed by the heater 30. The heater 30 may heat at least part of the edge of the substrate W based on the ejection signal synchronized with the encoder signal.

The operation S300 of obtaining vision information may be performed by the vision system 40. The vision system 40 may include a camera and an image processing module. The vision system 40 may capture an image of the edge of the substrate W by using the camera, process the captured image (or video) through the image processing module, and obtain the vision information.

The vision information may include a position of a solution (for example, the protective solution PLa) ejected onto the edge of the substrate W. For example, in the operation S300 of obtaining the vision information, the vision system 40 may determine the extent to which the solution applied to the substrate W flows down in the vertical direction (or whether the flow of the solution exceeds a reference value), whether there is a void between the first substrate W1 and the second substrate W2 (or whether the solution applied to the substrate W moves to the center of the substrate W to come into contact with the bonding layer BL), and so on, and the vision information may include results of the determination. As described above, the dispenser 20 and the heater 30 may operate based on the vision information of the vision system 40.

Hereinafter, an example of the substrate processing method according to the embodiment is described.

First, an encoder signal of the substrate stage 10 may be obtained (S100), and a solution may be ejected toward an edge of the substrate W for a first period according to an ejection signal synchronized with the encoder signal S200. Vision information including position information of the solution ejected to the edge of the substrate W may be obtained (S300), and the next process may be performed depending on whether the flow of the solution (in the vertical direction) is greater than or equal to a reference value (S350). When the flow of the solution is less than the reference value, the solution may be continuously ejected toward the edge of the substrate W.

When the flow of the solution is greater than or equal to the reference value, at least part of the edge of the substrate W may be heated for a third period. Therethrough, the solution applied to the substrate W may be cured. The current controller 32 may control a intensity, a cycle, and so on of the heater 30 to prevent the solution from being completely cured, and may heat a point where the solution flows down as a target. The embodiments are not limited thereto, and the heater 30 may completely cure the solution or uniformly heat the edge of the substrate W for the third period.

Thereafter, the solution may be ejected again toward the edge of the substrate W for the second period (S500). In this way, in order to control the horizontal flow and vertical flow of the solution, the operations S200 and S500) of ejecting the solution to the substrate W may be performed discontinuously (i.e., in time periods that are temporally spaced apart and non-overlapping).

After ejecting the target amount of solution to the edge of the substrate W for the second period, at least part of the edge of the substrate W may be heated for the fourth period (S600). For the fourth period, the heater 30 may pre-cure or completely cure the solution applied to the edge of the substrate W. In one embodiment, after the fourth period, the solution application operation S500 and the heating operation S600 may be repeated.

As described above, the first time period and the third time period of ejecting the solution toward the edge of the substrate W may be discontinuous from each other (i.e., the first and third time periods are temporally spaced apart and non-overlapping). The third period and the fourth period for heating at least part of the edge of the substrate W may be discontinuous from each other (i.e., the third and fourth time periods are temporally spaced apart and non-overlapping). In one embodiment, one of the first period and the second period may be between the third period and the fourth period.

In the substrate processing method according to the embodiment, the vision system 40 may control operation of the dispenser 20 and operation of the heater 30 by using vision information including various types of information. For example, the first period to the fourth period may be determined according to the vision information transmitted in real time. That is, the heating time and heating end time of the substrate W, and the ejection time and ejection end time of the solution may be determined based on the vision information.

The substrate processing apparatus 1 according to the embodiment may include the substrate stage 10, the encoder 16, the dispenser 20, the heater 30, and the vision system 40. The encoder 16 may obtain an encoder signal including rotation information of the substrate stage 10, and the dispenser 20 and the heater 30 may each operate in synchronization with the encoder signal. The vision system 40 may include a camera and an image processing module and obtain vision information including information, such as the degree of flow of the solution on the substrate W. Based on the vision information, not only whether the dispenser 20 and the heater 30 operate, but also the ejection speed and time of the solution, the intensity and time of the heater, and so on may be determined. Accordingly, the substrate processing apparatus 1 and the substrate processing method according to embodiments may control the horizontal and vertical flow of a solution applied to the substrate W.

The substrate processing apparatus and the substrate processing method using the same according to the inventive concept may control the flow of a solution ejected to an edge of a substrate through a heater and a dispenser synchronized with an encoder signal of a substrate stage. Also, based on a vision system, the heater and dispenser may operate at the necessary time to control the flow of a solution.

Accordingly, the substrate processing apparatus and the substrate processing method using the same according to the inventive concept may prevent damage, such as cracking and chipping of a wafer by forming a protective layer at an exact position of an edge of a substrate.

Herein, embodiments of the inventive are described with reference to the drawings but are merely examples, and those skilled in the art will understand that various modifications and equivalent other embodiments may be derived therefrom. Therefore, the true technical protection scope of the inventive concept should be determined by the technical idea of the appended patent claims.

While the inventive concept has been particularly illustrated and described with reference to embodiments thereof, it will be understood that various changes in form and details may be made therein without departing from the spirit and scope of the following claims.

What is claimed is:

1. A substrate processing apparatus comprising:
a substrate stage configured to support and rotate a substrate;
a dispenser configured to eject a solution toward an edge of the substrate; and
a heater configured to heat at least part of the edge of the substrate,
wherein operation of the dispenser and the heater are synchronized with a signal from an encoder associated with the substrate stage.

2. The substrate processing apparatus of claim 1, wherein
the substrate comprises a first substrate and a second substrate in contact with each other in a first direction, and
wherein the dispenser is configured to eject the solution to a space between the first substrate and the second substrate.

3. The substrate processing apparatus of claim 2, wherein the dispenser is configured to eject the solution in a second direction perpendicular to the first direction.

4. The substrate processing apparatus of claim 2, wherein the heater is spaced apart from the substrate in a second direction.

5. The substrate processing apparatus of claim 1, further comprising:
a vision system configured to capture at least one image of the edge of the substrate and to obtain vision information from the at least one image.

6. The substrate processing apparatus of claim 5, wherein the vision information comprises a position of the solution ejected from the dispenser.

7. The substrate processing apparatus of claim 5, wherein the dispenser and the heater are configured to operate based on the vision information.

8. The substrate processing apparatus of claim 7, further comprising:
a current controller configured to control intensity of the heater, based on the vision information.

9. The substrate processing apparatus of claim 1, wherein the heater is configured to heat the at least part of the edge of the substrate for multiple time periods.

10. The substrate processing apparatus of claim 1, wherein the heater is positioned adjacent to the edge of the substrate.

11. A substrate processing method comprising:
obtaining a signal from an encoder associated with a substrate stage that is configured to support a substrate;
ejecting a solution, via a dispenser, toward an edge of the substrate in response to an ejection signal that is synchronized with the encoder signal;
heating at least part of an edge of the substrate, via a heater, in response to a heat signal that is synchronized with the encoder signal; and
obtaining vision information by capturing an image of the edge of the substrate.

12. The substrate processing method of claim 11, wherein the vision information comprises a position of the solution ejected to the edge of the substrate.

13. The substrate processing method of claim 11, wherein,
the solution is ejected toward the edge of the substrate via the dispenser in a horizontal direction.

14. The substrate processing method of claim 13, wherein the dispenser is turned on or turned off in response to the vision information.

15. The substrate processing method of claim 13, wherein,
the ejecting of the solution toward the edge of the substrate via the dispenser comprises ejecting the solution during a first time period and a second time period that are temporally spaced apart and non-overlapping.

16. The substrate processing method of claim 15, wherein,
the heating of the at least part of the edge of the substrate via the heater comprises heating the at least part of the edge of the substrate during a third time period and a fourth time period that are temporally spaced apart and non-overlapping.

17. The substrate processing method of claim 16, wherein one of the first time period and the second time period is between the third time period and the fourth time period.

18. The substrate processing method of claim 16, wherein the heater is configured to be turned on or off based on the vision information.

19. The substrate processing method of claim 16, wherein,
the dispenser and heater are fixed and the substrate is rotated during the ejecting of the solution toward the edge of the substrate and the heating of the at least part of the edge of the substrate.

20. A substrate processing apparatus comprising:
a substrate stage configured to support a substrate including a first substrate and a second substrate in contact with each other in a first direction;
a dispenser configured to eject a solution in a second direction to a space between the first substrate and the second substrate, wherein the second direction is transverse to the first direction;
a heater positioned adjacent to the substrate in the second direction;
an encoder configured to generate an encoder signal including rotation information of the substrate stage;
a dispensing controller configured to control operation of the dispenser by using an ejection signal synchronized with the encoder signal;
a current controller configured to control operation of the heater by using a heat signal synchronized with the encoder signal; and
a vision system configured to obtain vision information by capturing an image of the substrate.
